(19) United States
(12) Patent Application Publication
(10) Pub. No.: US 2003/0148566 A1
(43) Pub. Date: Aug. 7, 2003

(54) Production method for flat panel display

(76) Inventors: Takashi Noguchi, Kanagawa (JP); Setsuo Usui, Kanagawa (JP); Hideharu Nakajima, Kanagawa (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 10/257,479

(22) PCT Filed: Apr. 11, 2001
(86) PCT No.: PCT/JP01/03131

(30) Foreign Application Priority Data
Apr. 11, 2000 (JP) 2000-109418
Apr. 11, 2000 (JP) 2000-109459

(51) Int. Cl. H01L 21/8238

(52) U.S. Cl. 438/200

(57) ABSTRACT

A method of manufacturing a flat panel display capable of manufacturing and preparing TFT of a pixel part and TFT of a scanning part with high reliability, comprising the steps of forming an amorphous silicon thin film on a substrate comprising a pixel part and a drive part, removing hydrogen from the amorphous silicon thin film formed in the drive part by irradiating a laser beam while without irradiating the amorphous silicon thin film formed in the pixel part, and crystallizing the amorphous silicon thin film formed in the drive part by irradiating a laser beam further, thereby changing the amorphous silicon thin film into a polycrystalline silicon thin film.

### TECHNICAL FIELD

The present invention relates to a method of manufacturing a flat panel display, and more specifically, to a method of changing an amorphous silicon thin film formed on a substrate on which a pixel part and a drive part are constituted into a polycrystalline silicon thin film having an excellent film quality.

### BACKGROUND OF ART

A liquid crystal display panel has been widely used heretofore as a display device for various electronic apparatuses. As a liquid crystal flat panel of this kind, that of an active matrix type has been used in which switching of a pixel is carried out by turning on and off a switching element formed on each pixel in a display part.

In the active matrix type liquid crystal display as described above, a thin film transistor (TFT) using an amorphous silicon thin film in a channel portion has been used as a switching element of a pixel part. This results from the fact that an amorphous silicon thin film can be formed uniformly with a good film quality over a large area. TFT using an amorphous silicon thin film in a channel portion has uniform characteristics and is high in off resistance, thus being suitable for use with a switching element of a pixel part. However, TFT of this kind is not suitable for use with a switching element in a scanning part comprising a horizontal scanning circuit or a vertical scanning circuit since carrier mobility of an amorphous silicon is low.

For solving a problem as noted above, there has been proposed a liquid crystal display panel wherein in a case where a horizontal scanning circuit or a vertical scanning circuit is formed on the same substrate as the pixel part, amorphous silicon is used in a channel portion of TFT constituting a switching element of a pixel part, and polycrystalline silicon is used in a channel portion of TFT constituting a switching element of a scanning part (See Japanese Patent No. 2,776,820 Publication).

In the liquid crystal display panel disclosed in the Japanese Patent No. 2,776,820 Publication, first polycrystalline silicon films are cumulated on a substrate, and patterning is applied thereto to thereby form a channel portion of TFT of a scanning part and a gate electrode of TFT of a pixel part; thereafter, separate polycrystalline silicon films are cumulated, and patterning is applied thereto to thereby form a gate electrode of TFT of a scanning part; and further amorphous silicon thin films are cumulated, and patterning is applied thereto to thereby form a channel portion of TFT of a pixel part, thus posing a problem that the steps become complicated.

On the other hand, there is known the art that by annealing process, an amorphous silicon thin film is polycrystallized and changed into a polycrystalline silicon thin film. However, in a case where by annealing process, an amorphous silicon thin film is polycrystallized, it has been difficult that an amorphous silicon thin film is polycrystallized into a polycrystalline silicon thin film having an excellent film quality due to the influence of hydrogen contained in the amorphous silicon thin film.

Further, the art of changing an amorphous silicon thin film into a polycrystalline silicon thin film by annealing process can be applied to various manufacturing processes of a semiconductor device such as not only a liquid crystal display panel but also an EL display panel. However, also in the annealing process in these various manufacturing processes of a semiconductor device, it has been difficult that an amorphous silicon thin film is polycrystallized into a polycrystalline silicon thin film having an excellent film quality due to the influence of hydrogen contained in the amorphous silicon thin film.

### DISCLOSURE OF THE INVENTION

It is an object of the present invention to provide a method of manufacturing a flat panel display to enable preparation of TFT of a pixel part and TFT of a scanning part by simple manufacturing steps.

It is a further object of the present invention to provide a method of manufacturing a flat panel display to enable polycrystallization of an amorphous silicon thin film into a polycrystalline silicon thin film having an excellent film quality.

For achieving the aforementioned objects, a method of manufacturing a flat panel display according to the present invention includes the steps of

forming an amorphous silicon thin film on a substrate comprising a pixel part and a drive part;

removing hydrogen from the amorphous silicon thin film formed in the drive part by irradiating a laser beam while without irradiating the amorphous silicon thin film formed in the pixel part; and

crystallizing the amorphous silicon thin film formed in the drive part by irradiating a laser beam further, thereby changing the amorphous silicon thin film into a polycrystalline silicon thin film.

According to the present invention, in the hydrogen removing step, hydrogen is removed from the amorphous silicon thin film formed in the drive part by irradiating a laser beam while without irradiating the amorphous silicon thin film formed in the pixel part without removing hydrogen from the amorphous silicon thin film formed in the pixel part. Then, in the crystallizing step, the amorphous silicon thin film formed in the drive part is crystallized to be changed into a polycrystalline silicon thin film. Thus, it becomes possible to form a hydrogen-contained amorphous silicon thin film in the pixel part, and to form a polycrystalline silicon thin film having a good film quality in a scanning part.

The hydrogen removing step and the crystallizing step are continuously carried out by the same laser annealing apparatus to thereby enable suppression of complicatedness of the steps.

In the hydrogen removing step, energy density of the laser beam irradiated on the amorphous silicon thin film formed in the drive part is set to, preferably, not less than 350 mJ/cm² and not more than 450 mJ/cm².

In the crystallizing step, energy density of the laser beam irradiated on the amorphous silicon thin film formed in the drive part is set to, desirably, 300 mJ/cm² to 750 mJ/cm².

Preferably, in the crystallizing step, energy density of the laser beam irradiated on the amorphous silicon thin film formed in the drive part is set to 400 mJ/cm² to 700 mJ/cm².

More preferably, in the crystallizing step, energy density of the laser beam irradiated on the amorphous silicon thin film formed in the drive part is set to 450 mJ/cm² to 650 mJ/cm².

In the hydrogen removing step and the crystallizing step, as the laser beam irradiated on an amorphous silicon thin film, an excimer laser beam is used.

As the excimer laser beam, an excimer laser beam selected from a group comprising an XeCl excimer laser beams, a KrF excimer laser beams, and an Arf excimer laser beams is used.

Particularly, according to the present invention, in the hydrogen removing step, an excimer laser beam having a large pulse width, for example, about 160 n sec is used, and energy density of the excimer laser beam is set to not less than 350 mJ/cm² and not more than 450 mJ/cm² whereby dehydrogenation, or removal of hydrogen, can be carried out without damaging the amorphous silicon thin film.

Further, in the crystallizing step, an excimer laser beam having a large pulse width, for example, about 160 n sec is used, and energy density of the excimer laser beam is set to 400 mJ/cm² to 650 mJ/cm² whereby a polycrystalline silicon thin film can be formed. Particularly, the operation for irradiating an excimer laser beam on an amorphous silicon thin film to carry out polycrystallizing under the aforementioned conditions is repeated plural times to thereby enable formation of a polycrystalline silicon thin film of higher quality.

In the present invention, the amorphous silicon thin film is formed on a substrate selected from a group comprising a glass substrate and a plastic substrate.

Further, the present invention comprises the step of patterning the amorphous silicon thin film formed in the pixel part and the polycrystalline silicon thin film formed in the drive part, thereby forming an amorphous silicon thin film pattern and a polycrystalline silicon pattern, respectively, wherein at least a part of the amorphous silicon thin film pattern is a channel portion of TFT of the pixel part, and at least a part of the polycrystalline silicon pattern is a channel portion of TFT of the drive part.

In the present invention, since the channel portion of TFT of the pixel part and the channel portion of TFT of the scanning part are formed by the same start material, the manufacturing step can be simplified.

Further, in the patterning step, patterning of the amorphous silicon thin film formed in the pixel part and patterning of the polycrystalline silicon thin film formed in the drive part are carried out simultaneously. Since patterning of the amorphous silicon thin film formed in the pixel part and patterning of the polycrystalline silicon thin film formed in the drive part are carried out simultaneously, the manufacturing step can be further simplified.

Other objects of the present invention, and the specific advantage obtained by the present invention will be further apparent from the explanation of the embodiment explained hereinafter.

### BRIEF DESCRIPTION OF THE DRAWINGS

FIG. 1 is a circuit view of a liquid crystal display panel to which the method of the present invention is applied.

FIG. 2 is a sectional view a device construction of TFT formed on a pixel part of the liquid crystal display panel to which the method of the present invention is applied and TFT formed on a scanning part comprising a horizontal scanning part and a vertical scanning part.

FIGS. 3 and 4 are respectively sectional views showing the manufacturing step for the liquid crystal display panel according to the method of the present invention is applied.

FIG. 5 is a schematic perspective view showing one example of a laser annealing apparatus used in the method of the present invention.

FIG. 6 is a sectional view showing the manufacturing step of a liquid crystal display panel according to the method of the present invention.

FIG. 7 is a view showing the temperature change of a thin film surface in a case where an XeCl excimer laser beam with the pulse width as 160 nsec on an amorphous silicon thin film while differentiating energy density.

FIG. 8 is a view showing a relationship between the shot number and the grain size of a polycrystalline silicon thin film obtained by crystallizing an amorphous silicon thin film in a case where an XeCl excimer laser beam having energy density of 500 mJ/cm² is irradiated on an amorphous silicon thin film having the film thickness of 40 nm.

FIG. 9 is a view showing a relationship between the energy density of an XeCl excimer laser beam and the grain size of a polycrystalline silicon thin film obtained by crystallizing an amorphous silicon thin film in a case where an XeCl excimer laser beam of the pulse width 160 nsec whose repetitive frequency is 1 Hz is irradiated, varying energy density, on amorphous silicon thin films different in the film thickness.

FIGS. 10, 11, 12 and 13 are respectively sectional views showing the manufacturing step of a liquid crystal display panel according to the method of the present invention.

### BEST MODE FOR CARRYING OUT THE INVENTION

The present invention will be described in detail hereinafter with reference to the drawings. The present invention is applied to a liquid crystal display panel as a flat panel display.

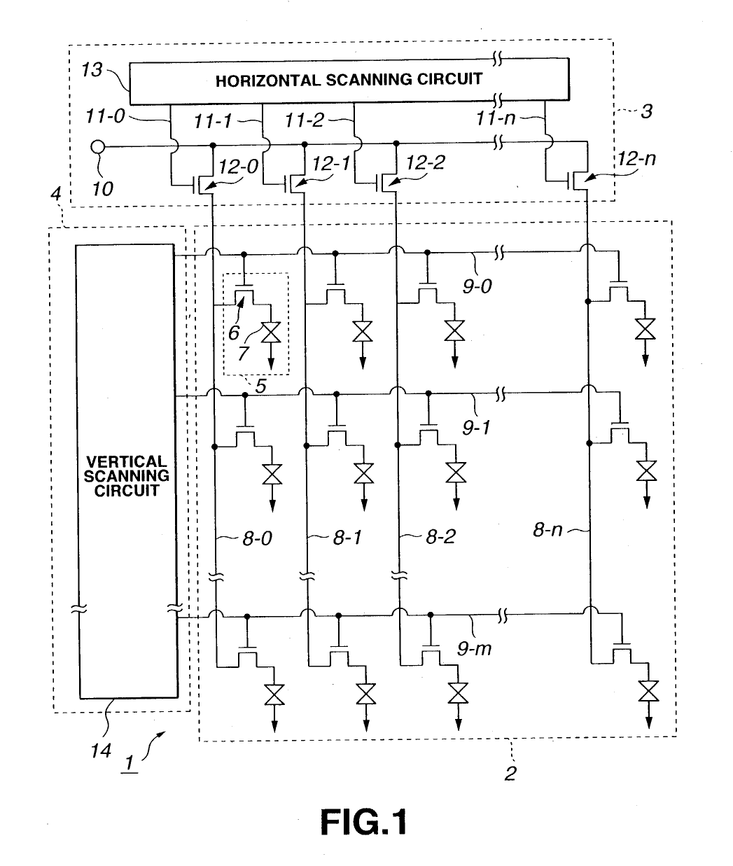

A liquid crystal display panel 1 to which the present invention is applied comprises, as shown in FIG. 1, a pixel part 2, a horizontal scanning part 3, and a vertical scanning part 4, which are formed on the same glass substrate.

The horizontal scanning part 3 includes a horizontal scanning circuit 13 and the (n+1) numbers of transistors 12-0˜12-n, and the (n+1) numbers of horizontal selection signal lines 11-0˜11-n are derived from the horizontal scanning circuit 13. These horizontal selection signal lines 11-0˜11-n are connected to gate electrodes of the corresponding transistors 12-0˜12-n.

A video signal end 10 is connected in common to one of source/drain ends of the transistors 12-0˜12-n, and corresponding video signal lines 8-0˜8-n are connected to the other of the source/drain ends of the transistors 12-0˜12-n. A video signal of an image projected on the liquid display panel 1 is supplied to the video signal end 10.

The vertical scanning part 4 includes a vertical scanning circuit 14, and the (m+1) numbers of gate wirings 9-0˜9-m are derived from the vertical scanning circuit 14. The pixel part 2 includes a plurality of pixels 5, and each pixel 5 comprises a TFT6 and a pixel electrode 7. The pixel 5 is arranged at an intersection between video signal lines 8-0˜8-n and gate wirings 9-0˜9-n, the gate of the TFT6 is connected to corresponding gate wirings 9-0˜9-n, and video signal lines 8-0˜8-n are connected to one of source/drain ends of the TFT6.

In the liquid crystal display panel 1 constituted as described above, the horizontal scanning circuit 13 sequentially selects the horizontal selection signal lines 11-0˜11-n, sequentially conducts the transisters 12-0˜12-n, and sequentially supplies video signals to the corresponding video signal lines 8-0˜8-n. Further, the vertical scanning circuit 14 sequentially selects the gate wirings 9-0˜9-m, and sequentially conducts the TFT6 to which the gate electrodes are connected. Thereby, video signals are sequentially supplied to the pixel electrodes 7 of a plurality of pixels 5 constituting the pixel part 2, and the desired image is projected on the liquid crystal display panel 1.

Next, the device construction of the liquid crystal display panel 1 to which the present invention is applied will be described hereinafter.

FIG. 2 is a sectional view showing the device construction of a TFT6 formed in the pixel part 2 of the liquid crystal display panel 1 to which the present invention is applied and a TFT50 formed in a scanning part comprising the horizontal scanning part 3 and the vertical scanning part 4.

The TFT6 formed in the pixel part 2 of the liquid crystal display panel 1 and the TFT50 formed in the scanning part comprising the horizontal scanning part 3 and the vertical scanning part 4 are formed on the same glass substrate 20 as shown in FIG. 2. Here, the TFT6 formed in the pixel part 2 is TFTs constituting the pixel 5 as shown in FIG. 1. The TFT50 formed in the scanning part comprising the horizontal scanning part 3 and the vertical scanning part 4 is TFTs included in the horizontal scanning circuit 13 or the vertical scanning circuit 14 shown in FIG. 1.

More specifically, on the glass substrate 20 is formed a bedding layer 21 formed of SiO₂, on the bedding layer 21 is formed, in the pixel part 2, a channel portion 22 formed of a hydrogenated amorphous silicon thin film, and source/drain portions 23 and 24, and in the scanning part comprising the horizontal scanning part 3 and the vertical scanning part 4 are formed a channel portion 30 formed of a polycrystalline silicon thin film and a source/drain portion 31. Any of these channel portion 22, source/drain portions 23 and 24, channel portion 30 and source/drain portion 31 are thin films formed using the cummulated hydrogenated amorphous silicon thin film as a start material by the same step. On these channel portion 22, source/drain portions 23 and 24, channel portion 30 and source/drain portion 31 are formed gate insulating films 25. On a portion for covering the channel portion 22 of the gate insulating film 25 is formed a gate electrode 9, and on a portion for covering the channel portion 30 of the gate insulating film 25 is formed a gate electrode 32. These channel portion 22, source/drain portions 23 and 24, gate insulating film 25 and gate electrode 9 constitute the TFT6 of the pixel part 2, and these channel portion 30, source/drain portions 31, gate insulating film 25 and gate electrode 32 constitute the TFT50 of the scanning part comprising the horizontal scanning part 3 and the vertical scanning part 4.

It is noted that the source/drain portion 24 constituting the TFT6 is connected to a pixel electrode 7 not shown in FIG. 2. On the TFT6 of the pixel part 2 and the TFT 50 of the scanning part are formed a layer to layer insulating film 26; in the pixel part 2 is provided a video signal line 8 connected to the source/drain portion 23 though a through-hole provided in the layer to layer insulating film 26; and in the scanning part comprising the horizontal scanning part 3 and the vertical scanning part 4 is provided an aluminum wiring 33 connected to the source/drain portion 31 though a through-hole provided in the layer to layer insulating film 26. Here, the video signal line 8 is formed by an ITO (transparent electrode).

Next, the manufacturing method of the liquid crystal display panel 1 to which the present invention is applied will be explained hereinafter.

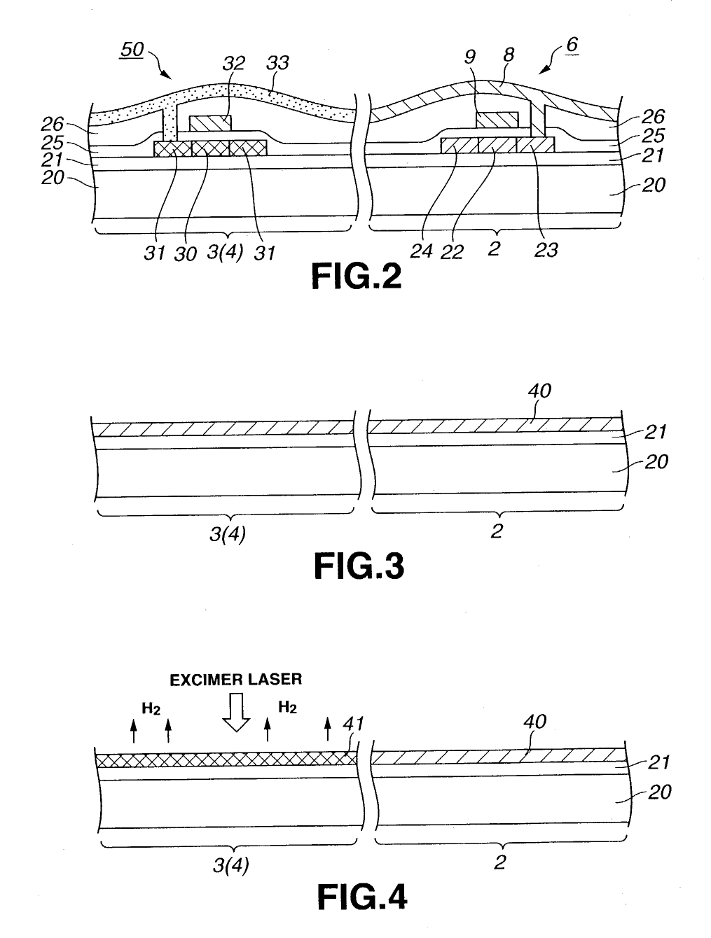

FIGS. 3, 4, 6, 10 to 13 are respectively sectional views showing, in order of steps, the manufacturing steps of the liquid crystal display panel 1 to which the present invention is applied.

In the method of the present invention, the bedding layer 21 formed of SiO₂ is cummulated on the whole surface of the glass substrate 20 by the plasma CVD method, and further, about 40 nm of a hydrogenated amorphous silicon thin film 40 of hydrogen concentration 5-30% is cummulated on the whole surface of the bedding layer 21, for example, by the plasma CVD method. The temperature condition when the hydrogenated amorphous silicon thin film 40 is cummulated is not more than 250° C.

By carrying out the aforementioned steps, the bedding layer 21 and the hydrogenated amorphous silicon thin film 40 are formed on both a portion to be the pixel part 2 and a portion to be the scanning part comprising the horizontal scanning part 3 and the vertical scanning part 4 on the glass substrate 20, as shown in FIG. 3.

Next, more than 10 shots of an XeCl excimer laser beam not less than 350 mJ/cm² and not more than 450 mJ/cm² are irradiated on only the scanning part comprising the horizontal scanning part 3 and the vertical scanning part 4 of the hydrogenated amorphous silicon thin film 40, as shown in FIG. 4.

As a result, hydrogen contained in the hydrogenated amorphous silicon thin film 40 formed in the scanning part comprising the horizontal scanning part 3 and the vertical scanning part 4 is removed and changed into an amorphous silicon thin film 41 rarely containing hydrogen (not more than 5%). At that time, an XeCl excimer laser beam is not irradiated on the hydrogenated amorphous silicon thin film 40 formed in the pixel part 2.

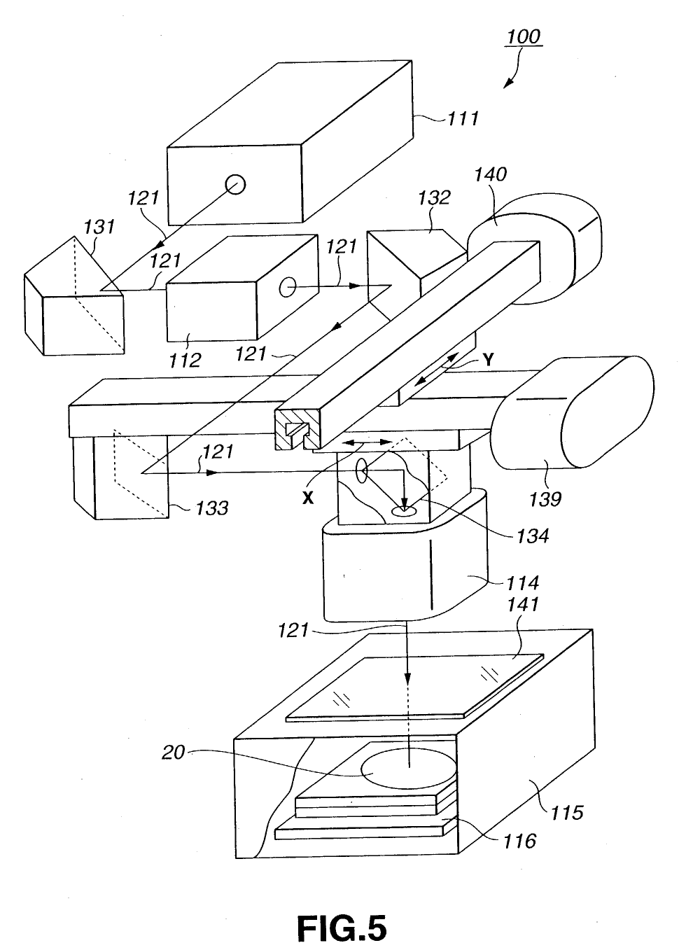

In the method of the present invention, a laser annealing apparatus 100 as shown in FIG. 5 is used. The laser annealing apparatus 100 is provided with a laser oscillator 111 for generating an XeCl excimer laser beam 121 (resonant wavelength 308 nm), as shown in FIG. 5. The laser oscillator 111 used in the laser annealing apparatus used in the present invention is constituted so as to generate a rectangular XeCl excimer laser beam 121. A first reflecting mirror 131 is provided in a light path of the XeCl excimer laser beam 121 generated from the laser oscillator 111, and the XeCl excimer laser beam 121 is reflected by the reflecting mirror 131 and is guided to an attenuator 112.

A second reflecting mirror 132 is provided in a light path of the XeCl excimer laser beam 121 having passed through the attenuator 112. The XeCl excimer laser beam 121 is reflected by the second reflecting mirror 132 and incident on a third reflecting mirror 132 mounted on a laser scanning mechanism 139 for scanning the XeCl excimer laser beam 121 and scanned in the X-axis direction. The second reflecting mirror 132 is mounted on a laser scanning mechanism 140 for scanning the the XeCl excimer laser beam 121 in the X-axis direction.

A fourth reflecting mirror 134 is provided in a light path of the XeCl excimer laser beam 121 reflected by the third reflecting mirror 133. The XeCl excimer laser beam 121 is reflected by the fourth reflecting mirror 134 and guided to a beam homogenizer 114. The XeCl excimer laser beam 121 is nearly uniformed in laser beam strength in a diametrical direction of light flux by the beam homogenizer 114.

A chamber 115 is arranged in a light path of the XeCl excimer laser beam 121 having passed through the beam homogenizer 114. The chamber 115 is internally provided with a stage 116 on which the glass substrate 20 is placed. Further, a transmission window 141 formed of quartz glass transmitting through the XeCl excimer laser beam 121 is provided above the chamber 115.

The XeCl excimer laser beam 121 incident on the chamber 115 is scanned on the hydrogenated amorphous thin film 40 (not shown) formed on the glass substrate 20 in the X-axis direction and in the Y-axis direction shown by the arrow in FIG. 5 by the laser scanning mechanism 139 and the laser scanning mechanism 140, whereby the XeCl excimer laser beam 121 is irradiated merely on the hydrogenated amorphous thin film 40 formed in the scanning part comprising the horizontal scanning part 3 and the vertical scanning part 4.

In the laser annealing apparatus 100 constituted as described above, the rectangular XeCl excimer laser beam 121 having energy density of the excimer laser beam is set to not less than 350 mJ/cm² and not more than 450 mJ/cm² is emitted from the laser oscillator 111. The XeCl excimer laser beam 121 is guided into the chamber 115 by an optical system.

The XeCl excimer laser beam 121 is scanned on the hydrogenated amorphous thin film 40 formed on the glass substrate 20 in the X-axis direction and in the Y-axis direction shown by the arrow in FIG. 5 by the laser scanning mechanism 139 and the laser scanning mechanism 140, and the XeCl excimer laser beam 121 is irradiated merely on the hydrogenated amorphous thin film 40 formed in the scanning part comprising the horizontal scanning part 3 and the vertical scanning part 4 of the hydrogenated amorphous thin film 40 formed on the glass substrate 20. The hydrogen contained in the hydrogenated amorphous thin film 40 formed in the scanning part comprising the horizontal scanning part 3 and the vertical scanning part 4 is removed by the energy of the XeCl excimer laser beam 121 thus irradiated and is changed into the amorphous silicon thin film 41 which rarely contains hydrogen (not more than 5%).

In the present invention, the rectangular XeCl excimer laser beam 121 is moved stepwise in the X-axis direction and in the Y-axis direction shown by the arrow in FIG. 5 with respect to the hydrogenated amorphous silicon thin film 40 so that continuous irradiation areas are overlapped in a fixed range by the laser scanning mechanism 139 and the laser scanning mechanism 140, and each area of the hydrogenated amorphous thin film 40 formed in the scanning part comprising the horizontal scanning part 3 and the vertical scanning part 4 of the hydrogenated amorphous thin film 40 is subjected to the irradiation of the XeCl excimer laser beam 121 of not less than 10 shots.

Alternatively, the irradiation according to the so-called step and repeat system may be carried out in which each area of the hydrogenated amorphous thin film 40 formed in the scanning part comprising the horizontal scanning part 3 and the vertical scanning part 4 is divided into some blocks, the laser beam is irradiated plural times (preferably, not less than 10 shots) while being fixed, the beam is moved to a separate block without overlapping, and the laser beam is irradiated plural times while being fixed.

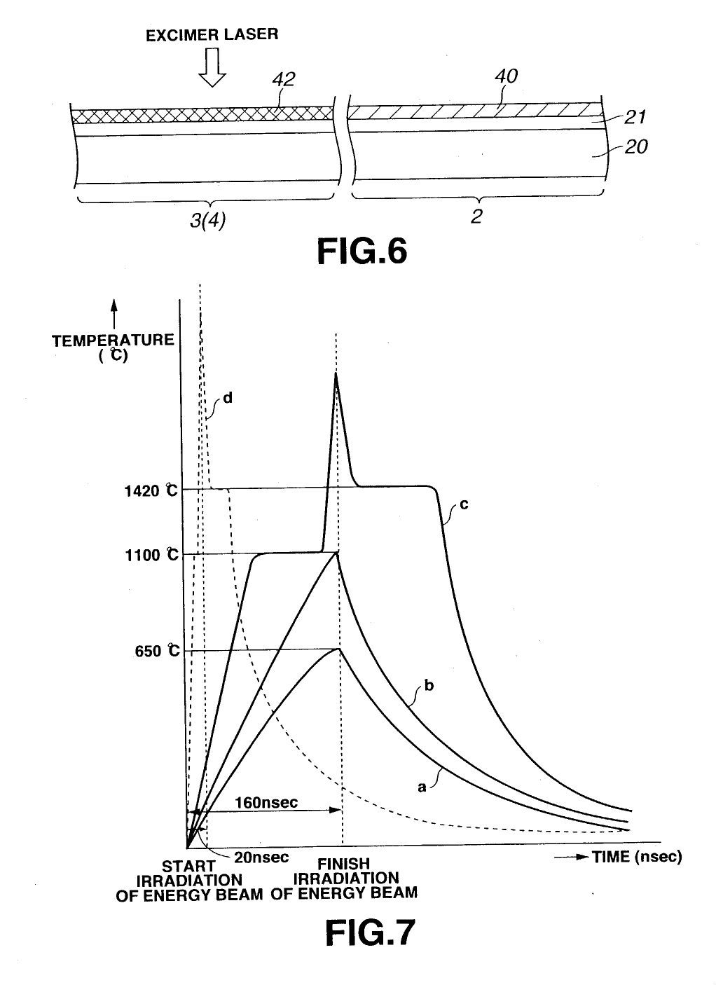

As described above, the hydrogen contained in the hydrogenated amorphous thin film 40 formed in the scanning part comprising the horizontal scanning part 3 and the vertical scanning part 4 is removed, and the hydrogenated amorphous thin film 40 is changed into the amorphous silicon thin film 41. Then, as shown in FIG. 6, the XeCl excimer laser beam 121 having energy density of the excimer laser beam of 400 mJ/cm² to 700 mJ/cm², preferably, 450 mJ/cm² to 750 mJ/cm² is irradiated, not less than 1 shot, on the amorphous silicon thin film 41 formed in the scanning part comprising the horizontal scanning part 3 and the vertical scanning part 4. Also in this case, as mentioned previously, the whole scanning part may be irradiated while overlapping the irradiation areas, or the irradiation may be done by the step and repeat system while dividing into a plurality of blocks. Thereby, the amorphous silicon thin film 41 formed in the scanning part comprising the horizontal scanning part 3 and the vertical scanning part 4 is crystallized and changed into the polycrystalline silicon thin film 42. At that time, the XeCl excimer laser beam is not irradiated on the hydrogenated amorphous thin film 40 formed in the pixel part 2.

Here, the irradiation of the XeCl excimer laser beam is carried out continuously to the step for removing hydrogen from the aforementioned hydrogenated amorphous thin film 40 by the laser annealing apparatus 100 shown in FIG. 5.That is, after the step for removing hydrogen from the aforementioned hydrogenated amorphous thin film has been finished, the strength of the XeCl excimer laser beam 121 emitted from the laser oscillator 111 is changed without removing hydrogen from the aforementioned hydrogenated amorphous thin film 40, and the crystallization of the amorphous silicon thin film 41 is carried out continuously.

The principle will be explained, with reference to FIG. 7, in which the amorphous silicon thin film 41 is subjected to the annealing process, dehydrogenation or crystallization and is changed into a polycrystalline silicon thin film.

The symbol a shows a time profile of a temperature of the film surface in a case where the excimer beam 121 having the pulse width of 160 nsec and energy density of 350 mJ/cm² is irradiated on the amorphous silicon thin film 41 formed with the thickness of 40 nm on the glass substrate. It has been confirmed that the surface temperature of the film at the time of termination of beam irradiation reaches 650° C., and hydrogen atom whose concentration is approximately 10 at % contained in the amorphous silicon thin film 41 becomes almost removed at that temperature, and the concentration is reduced to less than 5 at %.

The symbol b shows a time profile of in a case where the excimer beam 121 having the energy density of 450 mJ/cm² is irradiated on the amorphous silicon thin film, and the surface temperature of the film at the time of termination of radiation of the beam 121 reaches 1100° C. At this time, hydrogen atom contained in the form of a solid phase without being dissolved in the amorphous silicon thin film 41 becomes removed to less than 1 at %. When the excimer beam having the energy density of 450 mJ/cm² is irradiated on the amorphous silicon thin film 41, the surface of the film starts to dissolve, but in a case where a large quantity of hydrogen are contained in the amorphous silicon thin film 41, bumping of hydrogen occurs before the amorphous silicon thin film 41 becomes dissolved, and after the amorphous silicon thin film 41 becomes dissolved, hydrogen in the thin film 41 is removed more violently, resulting in the occurrence of damages such that pin holes are produced in the film or the film is peeled off from the substrate. The occurrence of damages caused by the removal of hydrogen in the thin film 41 is affected by the speed of the temperature rise of the amorphous silicon thin film 41. According to the experiences of the inventors, it has been considered that when the rising temperature of the amorphous silicon thin film 41 exceeds 10° C./nsec, the damage becomes great.

When an attempt is made to remove hydrogen atom contained in the amorphous silicon thin film 41 using the excimer laser beam 121 heretofore used having the pulse width less than 50 nsec, the temperature rising speed till the temperature from the start of irradiation to the removal of hydrogen atom is very fast, 50° C./nsec, as shown in the profile shown by the symbol d in FIG. 7 so that the amorphous silicon thin film 41 inevitably receives a breakage damage due to the removal of hydrogen. Even if the excimer laser beam 121 having the pulse width of 160 nsec is used, when the crystallizing process of the amorphous silicon thin film 41 is carried out without carrying out the dehydrogenation process by way of the laser beam, a damage of the amorphous silicon thin film 41 occurs. Accordingly, when the excimer laser beam 121 having the energy density less than 450 mJ/cm² is irradiated on the amorphous silicon thin film 41 to remove hydrogen atom contained in the amorphous silicon thin film 41 after which the crystallizing process of the amorphous silicon thin film 41 is carried out, the polycrystalline silicon thin film 42 free from damage can be prepared.

The dehydrogenation of the amorphous silicon thin film 41 progresses by the irradiation of the excimer laser beam 121 as described above, and the dehydrogenation operation is repeated plural times whereby the dehydrogenation of the amorphous silicon thin film 41 is carried out, and an amorphous silicon thin film suitable for the crystallization by way of the laser annealing can be obtained.

Incidentally, when the excimer laser beam 121 having the pulse width of 160 nsec and the energy density of 550 mJ/cm² is irradiated on the amorphous silicon thin film 41, the amorphous silicon thin film 41 uniformly starts melting from the surface at 1100° C., as in the time profile shown by the symbol c in FIG. 7. At this time, the temperature of the amorphous silicon thin film 41 remains substantially at 1100° C. When the amorphous silicon thin film 41 is completely molten, the temperature of the amorphous silicon thin film 41 rises again. When at this time, the irradiation of the excimer laser beam 121 stops, cooling of the amorphous silicon thin film 41 is started. When the temperature of the amorphous silicon thin film 41 becomes 1420° C. due to the cooling, a silicon crystal begins to grow, and the amorphous silicon thin film 41 is changed into the polycrystalline silicon thin film 42. At this time, the temperature of the polycrystalline silicon thin film 42 substantially remains at 1420° C. When the polycrystalline silicon thin film 42 is completely solidified, the temperature lowers again as in the time profile shown by the symbol c in FIG. 7. The crystallization of the amorphous silicon thin film 41 progresses through the process as described. The operation of the crystallization of the amorphous silicon thin film 41 is repeatedly carried out over plural times to thereby enable changing of the amorphous silicon thin film 41 into the polycrystalline silicon thin film 42.

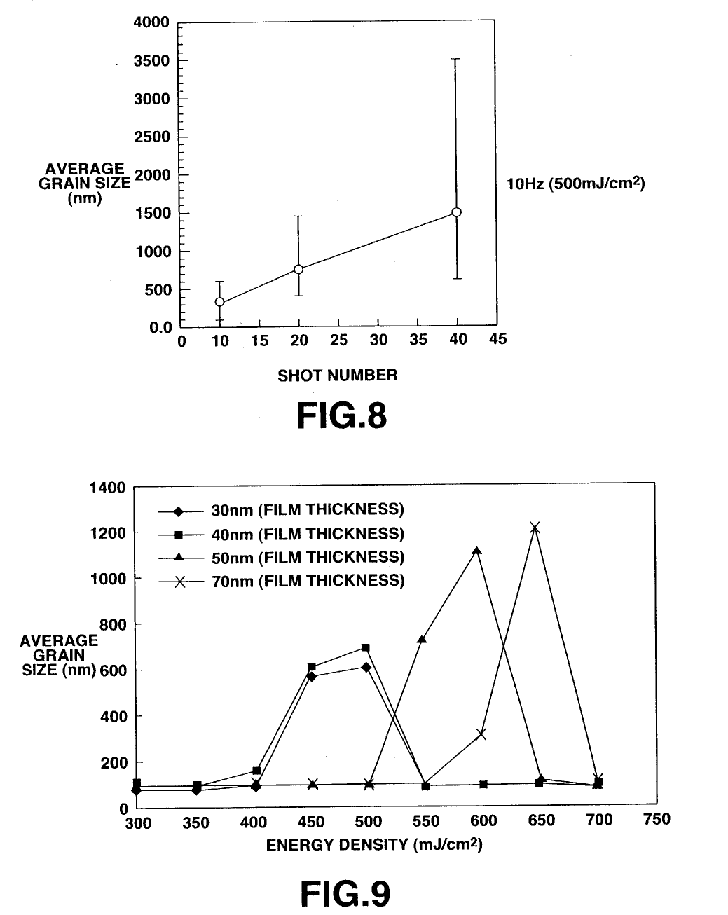

Now, a relationship between the shot number of the XeCl excimer laser beam 121 and the grain size of the polycrystalline silicon thin film 42 obtained by crystallization will be explained further with reference to FIG. 8.

FIG. 8 is a view showing a relationship between the shot number and the grain size of the polycrystalline silicon thin film 42 obtained by crystallization in a case where the XeCl excimer laser beam 121 having energy density of 500 mJ/cm² is irradiated on the amorphous silicon thin film 41 having the film thickness of 40 nm. The repeated frequency of the XeCl excimer laser beam 121 is 10 Hz.

As shown in FIG. 8, it is known that the more the shot number for irradiating the XeCl excimer laser beam 121, the crystalline grain size of the poly crystalline silicon thin film 42 obtained increases. Accordingly, the shot number of the XeCl excimer laser beam 121 may be set to a fixed shot number according to the crystal grain sise of the polycrystalline silicon thin film 42 required.

Further, the relationship between the shot number and the grain size of the polycrystalline silicon thin film 42 obtained by crystallization will be further explained with reference to FIG. 9.

FIG. 9 shows a relationship between the crystal grain size and the energy density in which energy density of the XeCl excimer laser beam 121 having the repeated frequency of 1 Hz is changed and crystallization process of the amorphous silicon thin film having the film thickness from 30 nm to 70 nm is carried out.

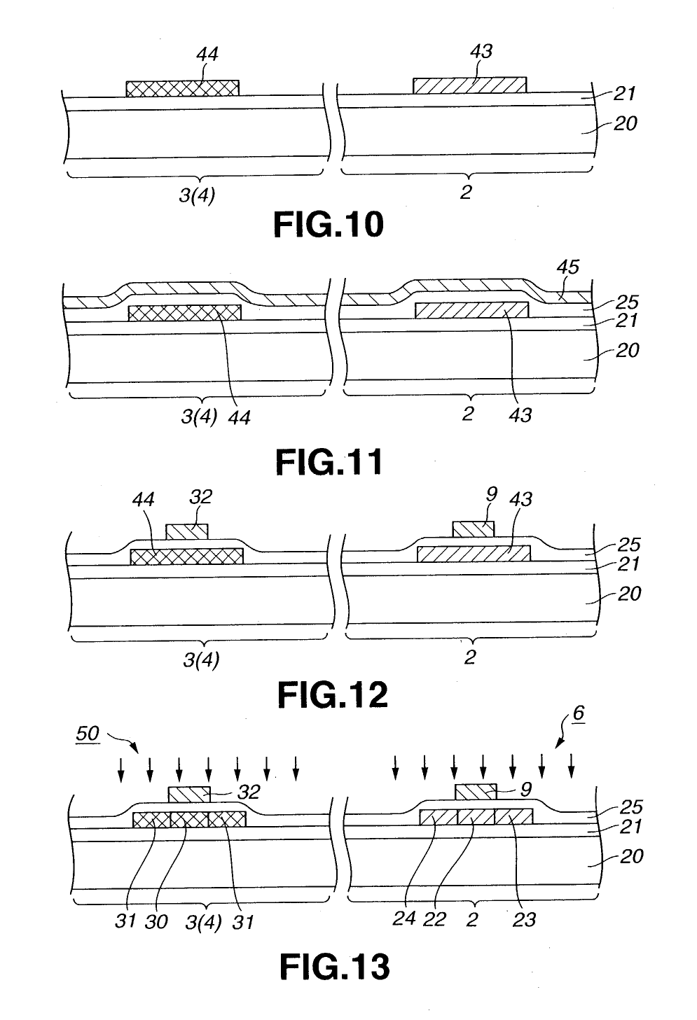

As will be apparent from FIG. 9, in the amorphous silicon thin film having the film thickness from 30 nm to 70 nm, when the energy density of the excimer laser beam 121 is 400 mJ/cm² to 550 mJ/cm², the increase effect of the silicon crystal grain size is remarkable. When the film thickness of the amorphous silicon thin film is 50 nm, the crystal grain size obtained when the energy density of the excimer laser beam 121 is 500 mJ/cm² to 650 mJ/cm² is large, and particularly, when the energy density is 550 mJ/cm² to 600 mJ/cm², the increase effect of the silicon crystal grain size is remarkable. When the film thickness of the amorphous silicon thin film is 70 nm, the crystal grain size obtained when the energy density of the excimer laser beam 121 is 600 mJ/cm² to 750 mJ/cm² is large, and particularly, the large grain size can be obtained in the vicinity of 650 mJ/cm². As the film thickness of the amorphous silicon thin film increases from 30 nm, the energy density of the excimer laser beam for polycrystallization increases, and the crystal grain size also becomes large. However, when the film thickness of the amorphous silicon thin film increases, the range of energy density for obtaining the large grain size becomes narrow, and the roughness of the surface of the polycrystalline silicon thin film obtained and the unevenness of the crystal grain size also become large. When the film thickness exceeds 70 nm, the large crystal grain in excess of 2 μm results, and therefore, the whole thickness of a film is not crystallized, failing to obtain a uniform polycrystalline silicon thin film. Accordingly, the range of energy density of the excimer laser beam substantially suitable for the crystallizing process is 300 mJ/cm² to 750 mJ/cm², preferably, 400 mJ/cm² to 700 mJ/cm², more preferably, 450 mJ/cm² to 650 mJ/cm². In the manner as described above, the amorphous silicon thin film 41 formed in the scanning part comprising the horizontal scanning part 3 and the vertical scanning part 4 is. changed into the polycrystalline silicon thin film 42, after which the hydrogenated amorphous silicon thin film 40 formed in the pixel part 2 is subjected to patterning as shown in FIG. 10 by the well known photolithography method to form the pattern 43, and the polycrystal silicon thin film 42 formed in the scanning part comprising the horizontal scanning part 3 and the vertical scanning part 4 is subjected to patterning to form the pattern 44. Patterning of the patterns 43 and 44 is carried out by the same step.

Next, as shown in FIG. 11, a gate insulating film 25 consisting of a silicon oxide is formed on the whole surface of the bedding layer 21 including the patterns 43 and 44, and an amorphous silicons film 45 is formed on the whole surface on the insulating film 25.

Next, as shown in FIG. 12, an amorphous silicon film 45 formed in the pixel part 2 is subjected to patterning by the well known photolithography method to form a gate electrode 9, and an amorphous silicon film 45 formed in the scanning part comprising the horizontal scanning part 3 and the vertical scanning part 4 is subjected to patterning to form a gate electrode 32. Patterning of the gate electrodes 9 and 32 is carried out by the same step.

Further, as shown in FIG. 13, ion injection is done for a pattern 43 and a pattern 44 with the gate electrodes 9 and 32 as a mask. With this, an area not subjected to the ion injection, due to the interposition of the gate electrode 9, of the pattern 43 formed in the pixel part 2 is a channel portion 22, and areas subjected to the ion injection is source/drain portions 23 and 24. Likewise, an area not subjected to the ion injection, due to the interposition of the gate electrode 32, of the pattern 44 formed in the scanning part comprising the horizontal scanning part 3 and the vertical scanning part 4 is a channel portion 30, and an area subjected to the ion injection is a source/drain portion 31. Such an ion injection as described is carried out with respect to the patterns 43 and 44 by the same step. Further, the irradiation of the excimer laser beam is carried out with respect to the source/drain portions 31, 23, 24 and the gate electrodes 9, 32 which are regions subjected to the ion injection to thereby enable activation of impurities and crystallisation of silicon thin films.

Then, the layer to layer insulating film 26 is formed on the whole surface, and the through-hole for opening the source/drain portions 23 and 31 is formed, after which an ITO electrode 8 connected to the source/drain portion 23 through the through-hole for opening the source/drain portion 23 is provided, and an aluminum electrode 33 connected to the source/drain portion 31 through the through-hole for opening the source/drain portion 31 is provided to obtain the construction shown in FIG. 2. Formation of the through-hole for opening the source/drain portion 23 and formation of the through-hole for opening the source/drain portion 31 are carried out by the same step.

As described above, in the liquid crystal display panel 1 obtained by the method according to the present invention, the channel portion 22 of TFT6 provided in the pixel part 2 and the channel portion 30 of TFT50 provided in the scanning part comprising the horizontal scanning part 3 and the vertical scanning part 4 have the hydrogenated amorphous silicon thin film 40 formed by the same step as a start material. Therefore, in preparation of TFTs 6 and 50, they are many steps that can be embodied in common, because of which TFT of the pixel part and TFT of the scanning part are prepared by the simple manufacturing step.

Further, according to the present invention, hydrogen contained in the hydrogenated amorphous silicon thin film 40 is first removed to the hydrogenated amorphous silicon thin film 40 formed in the scanning part comprising the horizontal scanning part 3 and the vertical scanning part 4 by dehydrogenation and changed into the amorphous silicon thin film 41, after which the amorphous silicon thin film 41 is changed into the polycrystalline silicon thin film 42, thus enabling preparation of the polycrystalline silicon thin film 42 having excellent film quality. Moreover, since the XeCl excimer laser beam 121 is not irradiated on the hydrogenated amorphous silicon thin film 40 formed in the pixel part 2, hydrogen is not removed from the hydrogenated amorphous silicon thin film 40 formed in the pixel part 2, because of which uncoupling of the hydrogenated amorphous silicon thin film 40 formed in the pixel part 2 can be less suppressed, thus providing excellent film quality also with respect to the hydrogenated amorphous silicon thin film 40 formed in the pixel part 2.

The present invention is not limited to the above-described embodiments, but various changes can be made within the scope of the invention described in claims, which are needless to say included in the scope of the present invention.

For example, while in the aforementioned invention, a description has been made taking an example of the liquid crystal display panel 1, the present invention is not limited thereto, but the present invention can be also applied to a flat panel display such as an EL display panel.

While in the aforementioned invention, the XeCl excimer laser beam 121 having the resonant wavelength 308 nm is used, excimer laser beams such as a KrF excimer laser beam (resonant wavelength 248 nm) or an ArF excimer laser beam (resonant wavelength 193 nm) may be used. The beams are not limited to an excimer laser beam, but other laser beams, and energy beams such as an electronic beam or a infrared beam can be used.

Furthermore, while in the aforementioned invention, the hydrogenated amorphous silicon thin film 40 is formed on the glass substrate 20, an amorphous silicon thin film may be formed on other substrates such as a plastic substrate in place of the glass substrate 20.

Further, while the laser annealing apparatus 100 shown in FIG. 5 is sued to irradiate the XeCl excimer laser beam 121 on the hydrogenated amorphous silicon thin film 40 and the amorphous silicon thin film 41, the present invention is not limited thereto but other laser annealing apparatuses can be used. For example, while in the laser annealing apparatus 100 shown in FIG. 5, the XeCl excimer laser beam 121 is scanned stepwise in the x-axis direction and in the y-axis direction by the laser scanning mechanisms 139 and 140, it is noted that the light path of the XeCl excimer laser beam 121 may be fixed to move the stage 116 itself in the x-axis direction and in the y-axis direction whereby the hydrogenated amorphous silicon thin film 40 and the amorphous silicon thin film 41 may be scanned.

Further, while the hydrogenated amorphous silicon thin film 40 and the amorphous silicon thin film 41 are scanned by the XeCl excimer laser beam 121 stepwise, they may be scanned continuously. Moreover, the XeCl excimer laser beam 121 may be irradiated plural times continuously on the whole surface of the hydrogenated amorphous silicon thin film 40 and the amorphous silicon thin film 41, and the beam may be irradiated on the places having been already irradiated plural times and heat-treated in order doubly.

Further, while in the above-described explanation, the rectangular XeCl excimer laser beam 121 is irradiated on the hydrogenated amorphous silicon thin film 40 and the amorphous silicon thin film 41 are scanned by the XeCl excimer laser beam 121, the shape of the rectangular XeCl excimer laser beam 121 is not limited to a rectangular shape, but the circular or linear rectangular XeCl excimer laser beam 121 may be used.

Further, while in the present invention, the dehydrogenation process of the hydrogenated amorphous silicon thin film 40 and the crystallizing process of the amorphous silicon thin film 41 are carried out continuously by the same laser annealing apparatus 100, it is noted that the processes have not always to be carried out continuously by the same laser annealing apparatus 100, but for example, the dehydrogenation process of the hydrogenated amorphous silicon thin film 40 and the crystallizing process of the amorphous silicon thin film 41 may be carried out by a separate laser annealing apparatus.

### INDUSTRIAL APPLICABILITY

In the present invention, the laser beam is not irradiated on the amorphous silicon thin film formed in the pixel part of the amorphous silicon thin film formed on the substrate, but by the hydrogen removing step for irradiating a laser beam on an amorphous silicon thin film formed in the drive part, hydrogen contained in the amorphous silicon thin film formed in the pixel part is not removed, but only hydrogen contained in the amorphous silicon thin film formed in the drive part is removed, after which the amorphous silicon thin film formed in the drive part is crystallized by the crystallizing process and changed into the polycrystalline silicon thin film, and therefore, it is possible that the amorphous silicon thin film containing hydrogen is formed in the pixel part and the polycrystal silicon thin film having excellent film quality is formed on the scanning part.

1. A method of manufacturing a flat panel display, comprising the steps of:
forming an amorphous silicon thin film on a substrate comprising a pixel part and a drive part;
removing hydrogen from the amorphous silicon thin film formed in the drive part by irradiating a laser beam while without irradiating the amorphous silicon thin film formed in the pixel part; and
crystallizing the amorphous silicon thin film formed in the drive part by irradiating a laser beam further, thereby changing the amorphous silicon thin film into a polycrystalline silicon thin film.

2. The method of manufacturing a flat panel display according to claim 1, wherein the hydrogen removing step and the crystallizing step are continuously carried out by the same laser annealing apparatus.

3. The method of manufacturing a flat panel display according to claim 1 or 2, wherein in said hydrogen removing step, energy density of said laser beam irradiated on the amorphous silicon thin film formed in said drive part is set to not less than 350 mJ/cm² and not more than 450 mJ/cm².

4. The method of manufacturing a flat panel display according to any of claim 1 to 3, wherein in said crystallizing step, energy density of said laser beam irradiated on the amorphous silicon thin film formed in said drive part is set to 300 mJ/cm² to 750 mJ/cm².

5. The method of manufacturing a flat panel display according to any of claim 1 to 3, wherein in said crystallizing step, energy density of said laser beam irradiated on the amorphous silicon thin film formed in the drive part is set to 400 mJ/cm² to 700 mJ/cm².

6. The method of manufacturing a flat panel display according to any of claim 1 to 3, wherein in said crystallizing step, energy density of said laser beam irradiated on said amorphous silicon thin film formed in said drive part is set to 450 mJ/cm² to 650 mJ/cm².

7. The method of manufacturing a flat panel display according to any of claim 1 to 6, wherein in said hydrogen removing step and said crystallizing step, said laser beam irradiated on said amorphous silicon thin film is an excimer laser beam.

8. The method of manufacturing a flat panel display according to claim 7, wherein said excimer laser beam is constituted by an excimer laser beam selected from a group comprising an XeCl excimer laser beam, a KrF excimer laser beam, and an Arf excimer laser beam.

9. The method of manufacturing a flat panel display according to claim 1, wherein said amorphous silicon thin film is formed on a substrate selected from a group comprising a glass substrate and a plastic substrate.

10. The method of manufacturing a flat panel display according to claim 1, further comprising the step of;
patterning the amorphous silicon thin film formed in said pixel part and the polycrystalline silicon thin film formed in said drive part, thereby forming an amorphous silicon thin film pattern and a polycrystalline silicon pattern, respectively, wherein at least a part of the amorphous silicon thin film pattern is a channel portion of TFT of said pixel part, and at least a part of said polycrystalline silicon pattern is a channel portion of TFT of said drive part.

11. The method of manufacturing a flat panel display according to claim 10, wherein in said patterning step, patterning of the amorphous silicon thin film formed in said pixel part and patterning of the polycrystalline silicon thin film formed in said drive part are carried out simultaneously.

12. The method of manufacturing a flat panel display according to claim 1, further comprising the steps of:
patterning the amorphous silicon thin film formed in said pixel part and the polycrystalline silicon thin film formed in said drive part;
forming an amorphous silicon thin film over said amorphous silicon thin film pattern and said polycrystalline silicon pattern; and
patterning said amorphous silicon thin film to constitute a gate electrode of TFT formed in said pixel part and said drive part.

13. The method of manufacturing a flat panel display according to claim 12, further comprising the step of:
applying an ion injection on the amorphous silicon thin film formed in said pixel part and the polycrystalline silicon thin film formed in said drive part using said gate electrode as a mask to constitute a source/drain of TFT formed in said pixel part and said drive part.

14. The method of manufacturing a flat panel display according to claim 1, further comprising the steps of:
patterning the amorphous silicon thin film formed in said pixel part and the polycrystalline silicon thin film formed in said drive part; and
forming a gate insulting film to cover the patterned amorphous silicon thin film formed in said pixel part and the patterned polycrystalline silicon thin film formed in said drive part.
